(19) United States
(12) Patent Application Publication
(10) Pub. No.: US 2022/0392718 A1
(43) Pub. Date: Dec. 8, 2022

(54) MONOLITHIC REMOTE CONTROL

(71) Applicant: fm marketing gmbh, Neumarkt am Wallersee (AT)

(72) Inventor: Ferdinand Maier, Neumarkt am Wallersee (AT)

(73) Assignee: fm marketing gmbh, Neumarkt am Wallersee (AT)

(21) Appl. No.: 17/887,991

(22) Filed: Aug. 15, 2022

Related U.S. Application Data
(63) Continuation of application No. 16/065,283, filed on Jun. 22, 2018.

(30) Foreign Application Priority Data
Dec. 23, 2015 (DE) 10 2015 016 784.7

(51) Int. Cl. H01H 9/02; B29C 45/40; B29C 65/00

(52) U.S. Cl. CPC H01H 9/0242; B29C 45/401; B29C 66/1162; B29C 66/54; B29C 66/71; B29L 2031/3481

(57) ABSTRACT

A plastic housing for remote controls, the housing comprising a first housing part and a second housing part, wherein the first housing part has a joining surface facing the second housing part, and the second housing part has a joining surface facing the first housing part, wherein the two housing parts are assembled such that the joining surfaces rest against each other, and wherein the joining surfaces are in the form of mitred surfaces.

### REFERENCE TO RELATED APPLICATIONS

This application is a continuation of U.S. application Ser. No. 16/065,283 filed Jun. 22, 2018, which is a US national stage application based on PCT/EP2016/082031 filed Dec. 20, 2016, and claims priority to DE 10 2015 016 784.7 filed Dec. 23, 2015, the entire disclosures of which are expressly incorporated herein by reference.

### FIELD OF THE INVENTION

The present invention relates to a plastic housing for electronic devices, in particular remote controls.

### BACKGROUND

Such a plastic housing is known for example from DE 10 2010 045 944 A1. It comprises a first housing part and a second housing part, wherein the first housing part has a joining surface facing the second housing part, and the second housing part has a joining surface facing the first housing part, wherein the two housing parts are assembled such that the joining surfaces rest against each other.

### SUMMARY OF THE INVENTION

According to one aspect of the invention, a plastic housing for electronic devices, in particular remote controls, comprises a first housing part and a second housing part, wherein the first housing part has a joining surface facing the second housing part, and the second housing part has a joining surface facing the first housing part, wherein the two housing parts are assembled such that the joining surfaces rest against each other, and wherein the joining surfaces are designed as mitred surfaces.

The said plastic housing is based on the idea that the plastic housing mentioned at the outset comprises interlocking elements which enlarge the joining surface and thus provide the two housing parts with a wider surface of contact with each other. However, the problem with the interlocking elements consists in the fact that they must be adjusted precisely to one another because otherwise a gap will remain between the two housing parts in the assembled state of the plastic housing, which gap might be considered to disrupt high aesthetic requirements. In order to avoid this gap, and to still achieve a large joining surface between the two housing parts, by means of the said plastic housing, it is proposed to form the joining surfaces as mitred surfaces.

In an embodiment of the said plastic housing, the mitred surfaces of the housing parts are formed at least in part so as to revolve around an interior space which is designed to enclose an electronic component of the electronic device. In this way, the mitred surfaces extend in a V-shape, and make it possible to additionally centre the two housing parts relative to each other. The mitred surfaces thus also fulfil the function of the above-mentioned interlocking elements.

In an additional embodiment of the said plastic housing, the mitred surfaces are formed so as to lead into the interior space. In this way, all blunt edges on the housing parts formed by the mitred surfaces are located in the interior space of the plastic housing. In the manufacturing process of the housing parts, tools such as ejector pins, deaeration elements or similar may be used particularly advantageously in the interior space, so that any remaining burrs or similar are no longer visible afterwards.

In another embodiment, the said plastic housing is produced by a method in which a casting material is introduced into the mould cavities forming the housing parts, and air is removed from the mould cavities at deaeration points which are positioned at or next to points in the mould cavities, at which the mitred surfaces of the housing parts are formed.

The embodiment is based on the idea that the introduction of the casting material into the mould cavity forces out the air present therein, and therefore the air has to be removed from the mould cavity. Usually, the air is removed from the mould cavity at a parting plane between the mould parts forming the mould cavity. In order for the mitred surfaces and thus the mould parts to extend in as precisely pointed a manner as possible, the parting planes should be as tight as possible at this point, so that no casting material enters the parting plane and thus leaves a burr that would be considered disruptive. Due to this tight design of the parting planes, a deaeration of the mould cavity at the parting plane is virtually eliminated. It is therefore proposed to position the deaeration point on or next to the mitred surface, preferably in the interior space to be formed of the plastic housing, so that the deaeration firstly takes place as closely as possible to the mitred surface to be formed, and thus no burns, inclusions or similar, which are considered disruptive, can be formed, however, secondly, burrs or similar resulting from production can be arranged in the interior space to be formed of the plastic housing.

In an embodiment of the said method, channels leading into the mould cavities into which ejector pins are inserted are used to remove the air from the mould cavities. In this way, firstly, the air channel through which the air is removed from the mould cavity is kept very small, so that accordingly less casting material enters the deaeration channel after completely deaerating the mould cavity. Secondly, the deaeration channel is automatically cleaned by the ejector pin when the cast housing part is ejected.

In a further embodiment of the said plastic housing, the casting material is introduced into the mould cavities at the injection points which are arranged on a side of the mould cavity opposite the side having the deaeration point.

In a particular embodiment of the said plastic housing, the injection points are arranged in the centre of the mould cavities when viewed in an injection direction of the casting material. In this way, it is ensured that the casting material can be distributed evenly in all directions of the mould cavity. However, it is additionally ensured that the casting material penetrates the pointed regions of the mould cavity last, and thus does not harden prematurely therein, which could cause the mould cavity to become clogged.

In a further embodiment of the said plastic housing, the mould cavities are formed with moulding plates which are closed in an airtight manner at a parting plane before the casting material is introduced into the mould cavities. In this way, the above-mentioned burr at the parting plane in the mould cavity is avoided.

In a preferred embodiment of the said plastic housing, the mitred surfaces of the housing parts to be formed lead into the parting plane.

In a particularly preferred embodiment of the said plastic housing, the deaeration points on the mitred surfaces are opposite the parting plane. In this way, it is ensured that burrs or similar resulting from the deaeration are arranged in the interior space to be formed of the plastic housing, and are not visible from the outside.

According to a further aspect of the invention, in a method to produce a housing part, a casting material is introduced into a mould cavity forming the housing part for one of the said plastic housings, and air is removed from the mould cavity at a deaeration point which is located at or next to a point in the mould cavity, at which the mitred surface of the housing part is formed.

In a further embodiment of the said method, a channel leading into the mould cavity, into which channel an ejector pin is inserted, is used to remove the air from the mould cavity.

In another embodiment of the said method, the casting material is introduced into the mould cavity at an injection point which is arranged on a side of the mould cavity opposite the side having the deaeration point.

In an additional embodiment of the said method, the injection point is arranged on a central axis of the mould cavity.

In a further embodiment of the said method, the mould cavity is created using two moulds which are closed in an airtight manner at a parting plane before the casting material is introduced into the mould cavity.

In a particular embodiment of the said method, the mitred surfaces of the housing part to be formed lead into the parting plane.

In a particularly preferred embodiment of the said method, the deaeration point on the mitred surface is opposite the parting plane.

According to a further aspect of the invention, a housing part of one of the said plastic housings is produced by one of the said methods.

### BRIEF DESCRIPTION OF THE DRAWINGS

The above-described properties, features and advantages of this invention, as well as the manner in which they are achieved, will become clearer in connection with the following description of the embodiments, which are described in more detail in connection with the drawings, in which:

FIG. 1 is a perspective view of a remote control;

FIGS. 2a to 2c are details of sectional views of a casting tool to produce a first housing part for a plastic housing of the remote control from FIG. 1;

FIGS. 3a to 3c are details of sectional views of a casting tool to produce a second housing part for the plastic housing of the remote control from FIG. 1;

FIG. 4 is a perspective view of a part of a casting tool to produce the plastic housing for the remote control from FIG. 1;

FIG. 5 is a partial view of the part of the casting tool from FIG. 4 from a different perspective,

FIG. 6 is a perspective view of a further part of the casting tool to produce the plastic housing for the remote control from FIG. 1;

FIGS. 7a and 7b are sectional views of the plastic housing of the remote control from FIG. 1; and

FIGS. 8a and 8b are interior views according to the upper casing and lower casing of the plastic housing of the remote control from FIG. 1.

In the drawings, like technical elements are provided with the same reference signs, and are only described once. The drawings are purely schematic, and, in particular, do not reflect the actual geometric proportions.

### DETAILED DESCRIPTION OF PREFERRED EMBODIMENTS

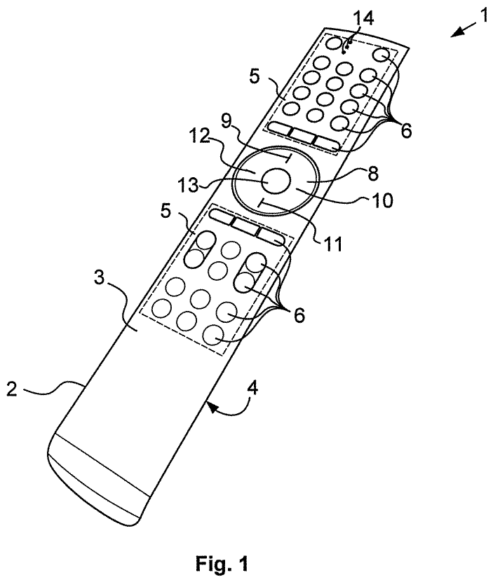

Reference is made to FIG. 1, which shows a remote control 1 to control an electronic device (not shown in further detail), such as a multimedia device, in a perspective view.

The remote control 1 comprises a plastic housing 2 having a first housing part composed of an upper casing 3 and a second housing part as a lower casing 4, as well as two keypads 5 having a plurality of key elements 6. For the sake of clarity, not all of the key elements 6 in the keypad 5 are provided with reference signs in the drawings.

A directional pad 8 is arranged between the two keypads 5, which directional pad comprises a first key element 9, a second key element 10, a third key element 11, and a fourth key element 12. The four key elements 9 to 12 are arranged circumferentially and at a distance of 90° from one another around a confirmation key 13. The directional pad 8 having the four key elements 9 to 12 is designed as circular disc in this case. The remote control 1 also comprises feedback elements 14 in the form of small lights which can light up when a key is pressed on the remote control 1.

This remote control 1 is used as an example to explain the operation of a multimedia device. To this end, a user uses the keys 5 on the upper casing 3 of the remote control 1 to enter control commands into the remote control 1 in the form of data which is then transmitted to the electronic device to be controlled via a transmitter (not shown in further detail). Such a command can be entered, for example, as a direction command via the key elements 9 to 12, which command then controls the movement of a control element on the exemplary multimedia device in one of the four possible directions of movement.

The illustration of the remote control 1 is given only by way of example to make it easier to understand the following technical designs. They may be implemented, however, in any desired electronic device and in particular in any desired remote control.

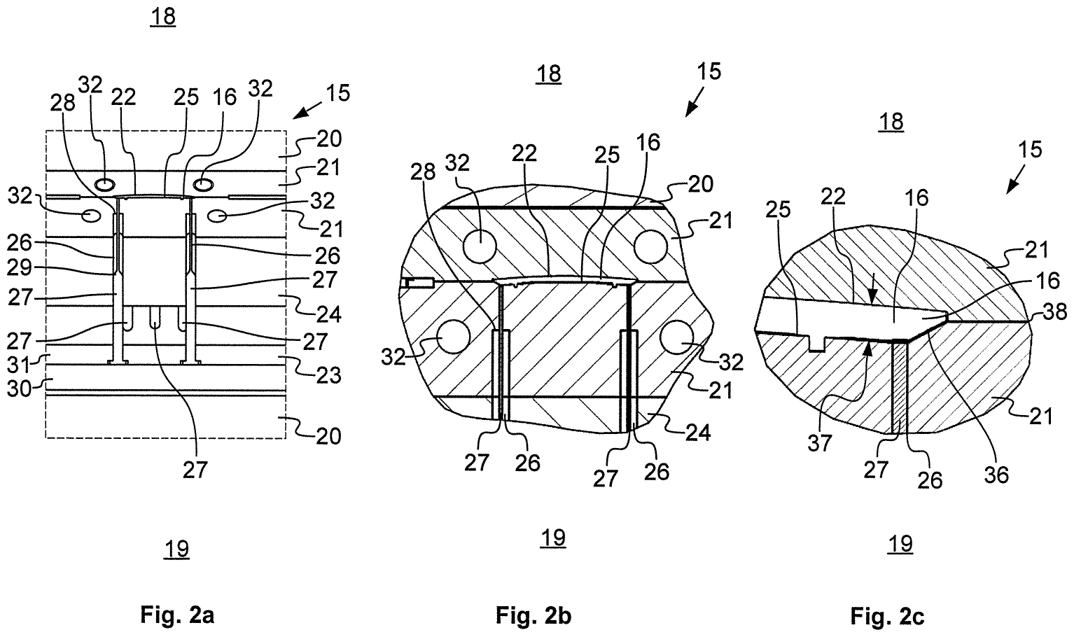

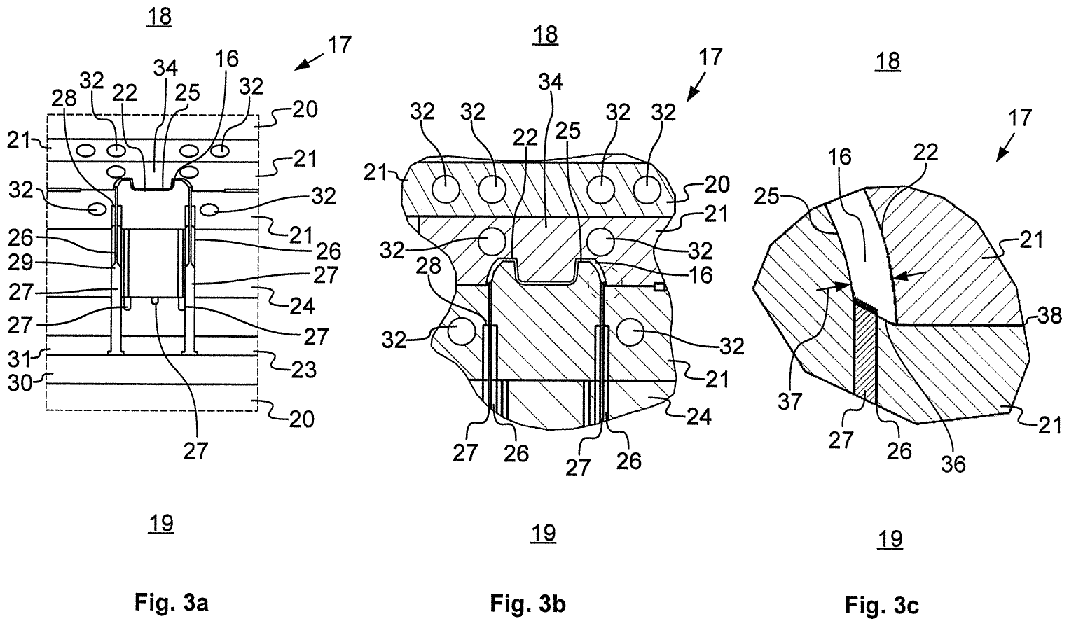

The plastic housing 2 is produced by primary forming which shall be described in the following technical designs on the basis of injection moulding. FIGS. 2a to 2c are details of sectional views of a permanent mould for an upper casing 15 to provide a mould cavity 16 for injection moulding the upper casing 3 of the plastic housing 2. In contrast, FIGS. 3a to 3c are details of sectional views of a permanent mould for a lower casing 17 to provide a mould cavity 16 for injection moulding the lower casing 4 of the plastic housing 2.

The permanent mould for an upper casing 15 comprises a pressure side 18, also referred to as nozzle side 18. The permanent mould for an upper casing 15 opposing the pressure side 18 comprises a locking side 19, also referred to as ejector side 19. On the pressure side 18 and locking side 19, the permanent mould for an upper casing 15 is enclosed by two mounting plates 20 which support the rest of the elements of the permanent mould for an upper casing 15.

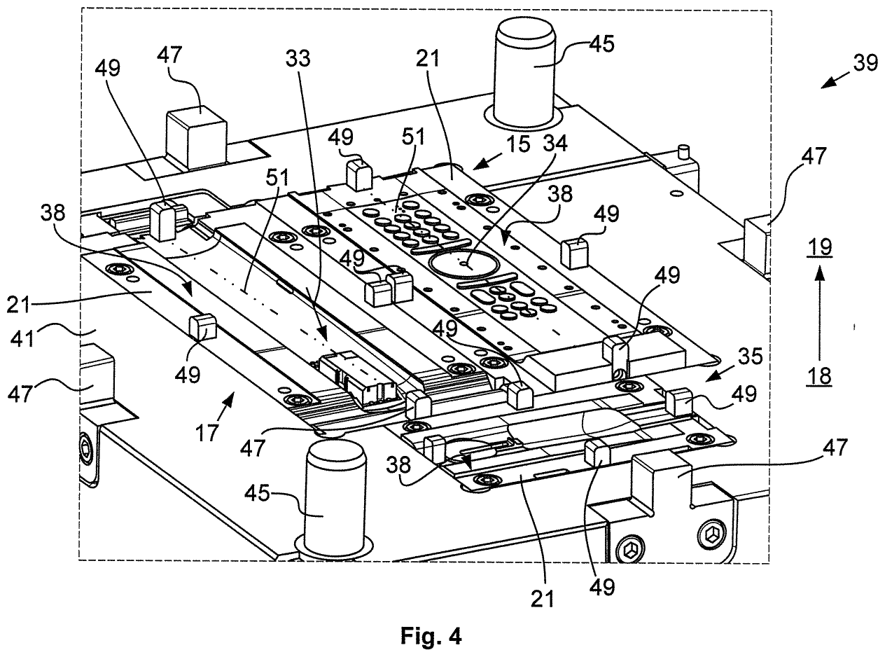

On the pressure side 18, the mounting plate 20 supports a moulding plate 41 as shown in FIG. 4, into which a mould insert 21 is inserted. A pressure matrix 22 is moulded into the mould insert 21, which matrix forms the convex outer surface of the plastic housing 2 on the upper casing 3.

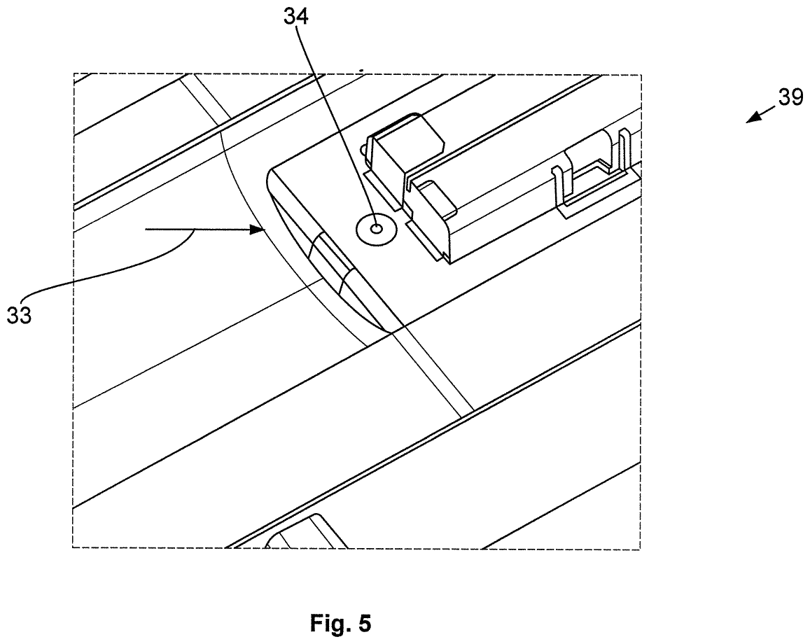

On the locking side 19, the mounting plate 20 supports an ejector housing 23 which is locked by a pressure plate 24 on the side opposing the mounting plate 20. The pressure plate 24 supports a moulding plate 41 (shown in FIG. 5) on the locking side, into which plate a mould insert 21 is inserted on the locking side. A core 25 is moulded onto the mould insert 21 on the locking side, which core forms the concave inner face of the plastic housing 2 on the upper casing 3.

The matrix 22 and the core 25 together form the mould cavity for the upper casing 16. In the mould cavity for the upper casing 16, guide channels 26 pass through the pressure plate 24 and the mould insert 21 on the locking side, in which channels ejector pins 27 are guided. The guide channels 26 comprise shoulders 28 which could be hit by the ejector pins 27 having corresponding counter-shoulders 29. For the sake of clarity, not all the shoulders 28 and counter-shoulders 29 are given reference signs in FIGS. 2a and 2b. These shoulders 28, 29 are required by the design because an upper part of each ejector pin 27 is in the form of a flat ejector pin, whereas the lower part of each ejector pin 27 is in the form of a round ejector pin for reasons relating to production and stability to increase the bending strength. The flat ejector pins of the ejector pins 27 are guided in the guide channels 26, whereas the round regions of the ejector pins 27 below the shoulders 29 are guided in clearance holes (no references).

The ejector pins 27 are supported on an ejector base plate 30 and are held in position by an ejector mounting plate 31. The two plates 30, 31 are arranged so as to be able to move inside the ejector housing 23, so that the ejector pins 27 can be moved via said plates.

Tempering holes 32 extend through the pressure plates 21 on the pressure side 18 and on the locking side 19, through which holes a tempering medium such as water can be guided to bring the mould cavity for the upper casing 16 to the correct temperature by cooling or heating. For the sake of clarity, not all these tempering holes 32 are given their own reference signs. The tempering holes 32 are at a minimum distance from the mould cavity 16, which is 10 to 20 times smaller than the width of the upper casing 3 of the plastic housing 2. The minimum distance in the present design is 2 mm. The diameter of the tempering holes 32 is between 4 and 5 times the size of the minimum distance. In the present design, this would be between 8 mm and 10 mm. The bigger the tempering holes 32, the faster the mould cavity is brought to the correct temperature.

The permanent mould for a lower casing 17 is designed in the same way as the permanent mould for an upper casing 15. This is the reason why the same reference signs are used in FIGS. 3a to 3c as in FIGS. 2a to 2c. The descriptions relating to the permanent mould for an upper casing 15 which were given previously apply similarly to the permanent mould for a lower casing 17. This is why it is not described again for the sake of brevity.

The only difference from the permanent mould for an upper casing 15 is that two mould inserts 21 are inserted in the moulding plate (not shown) of the permanent mould for a lower casing 17 on the pressure side 18, which inserts correspondingly produce a plurality of tempering holes 32 in the permanent mould for a lower casing 17.

The permanent mould for an upper casing 15 and the permanent mould for a lower casing 17 can be arranged together with another permanent mould 35 shown in FIGS. 4 and 5 to produce a battery lid in the same tool, which will be discussed in further detail later.

A variothermal injection moulding process is applied to produce an upper casing 3 and/or a lower casing 4. Usually, in injection moulding, in particular of plastic material, tempering is understood to mean cooling to dissipate the thermal energy of the molten casting material. However, in a variothermal injection moulding process, the mould cavity 16 is firstly heated before the casting material is injected, and then cooled down again. In the present design, the mould insert 21 is brought to the correct temperature equally on the pressure side 18 and on the locking side 19, i.e. heated first. In this way, in particular when injection moulding high-gloss housing parts 3, 4, it is ensured that the final product is free of weld lines.

The corresponding mould cavity 16 is closed independently of the heating process. To this end, the mounting plate 20 on the locking side 19 is moved relative to the mounting plate 20 on the pressure side 18 until the two moulding plates 21, in which the matrix 20 and the core 25 are formed correspondingly, are in contact.

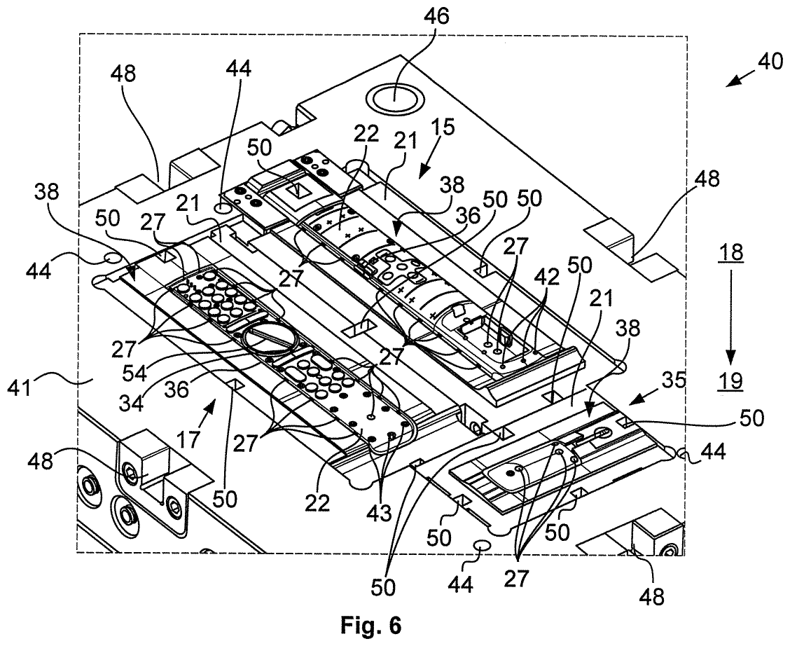

If the mould cavity 16 is closed and heated accordingly, the heated casting material is pressed into the mould cavity 16 via a sprue 34 shown in FIGS. 5 and 6. Methyl methacrylate acrylonitrile butadiene styrene, known by the abbreviation M-ABS, can be used as a casting material for the casings 3, 4 for a high-gloss plastic housing 2. This casting material should be heated up to 114° C. before being injected into the mould cavity 16.

The casting material injected into the mould cavity 16 disperses therein and displaces the air present therein. This must be discharged accordingly, which is described in more detail later.

Once the mould cavity 16 is completely filled with casting material, the mould inserts 21 are cooled down again via the tempering holes 32, so that the casting material hardens. For this purpose, cold water, for example, is driven through the tempering holes 32.

The mould cavity 16 is then opened, and the moulded part produced in this manner is ejected from the tool by means of the ejector pins 27. To this end, the ejector base plate 30 pushes the ejector pins 27 against the open mould cavity 16, so that the moulded part produced there, i.e. the upper casing 3 or the lower casing 4, is released and can fall out of the tool. The ejector pins 27 are then pulled back from the ejector base plate 31, and the entire tool is reset to the starting state, so that the injection moulding process can be restarted.

The intention of the present embodiment is to provide the plastic housing 2 of the remote control 1 with as monolithic a design as possible. If, for this purpose, the upper casing 3 and the lower casing 4 are joined at a joining surface 36, a butt joint between the two casings 3, 4 shall be positioned on an edge, so that as far as possible, no gap is visible between the two casings 3, 4. In this way, the observer would hardly be able to recognise whether the plastic housing 2 of the remote control 1 is a single-piece or a multi-piece component. In this way, the remote control 1 is provided with a significantly slimmer appearance, in particular when the upper casing 3 is designed in a colour contrast to the lower casing 4.

To this end, the joining surfaces 36 on the two casings 3, 4 are formed in such a way that the two casings 3, 4 can be joined by means of a mitre connection. This is why the joining surfaces 36 are to be referred to in the following as mitred surfaces 36. In producing the mitred surfaces 36, however, it must be noted that this may lead to differences in the wall thickness 37 of the casings 3, 4 to be produced, which can result in defects in the surfaces of the casings 3, 4 to be produced. However, to best achieve the above-mentioned monolithic effect, the casings 3, 4 must taper as much as possible at the mitred surfaces 36. This implies that the wall thickness 37 decreases from a standard wall thickness of, for example, 2 mm to a wall thickness of below 0.2 mm. This is why it must be ensured, when using the injection moulding process described previously, that the formation of surface defects such as burns on the casings 3, 4 is not promoted as a result of the big differences in the wall thickness 37.

In principle, a parting plane 38 between the mould inserts can be used for the above-mentioned deaeration of the mould cavity 16. For this purpose, a gap must remain in the parting plane, through which gap the air may escape outwards from the mould cavity 16. However, once the mould cavity 16 is deaerated completely, casting material penetrates up to this point, thus producing burrs. Such burrs, however, contradict in particular the desired monolithic appearance of the plastic housing 2, which is why deaeration via the parting plane 38 is ruled out.

For this reason, in the present embodiment, ejector pins 27 are arranged towards the inner face of the plastic housing 2 to be produced in the region of the mitred surfaces 36. The guide channels 26 and the ejector pins 27 can be formed in such a way that a sufficient gap remains between them to deaerate the mould cavity 16.

An advantage of this solution is that, when ejecting the produced moulded part, i.e. one of the casings 3, 4, the guide channels 26 are cleaned at the same time due to the movement of the ejector pins 27. Furthermore, the air can escape again from the guide channels 26 when the produced moulded part is ejected.

Furthermore, the mould inserts 21, each creating a mould cavity 16, always have to be placed precisely on top of each other in order to ensure a precisely extending mitred surface 36. This positioning shall be described in more detail in the following with reference to FIGS. 4 to 6 showing a perspective view of a half 39 of an injection moulding tool on the pressure side and a half 40 on the locking side accordingly, in which injection moulding tool the permanent mould for an upper casing 15, the permanent mould for a lower casing 17, and the permanent mould for the battery lid 35 are formed together. The mould inserts 21 of the corresponding permanent moulds 15, 17 and 35 are held in the moulding plates 41.

Further details can be seen in the cores 22 of the mould inserts 21 of the half 40 on the locking side, which cores are used to produce the casings 3, 4. FIG. 5, for example, shows pin-moulding elements 42 and sleeve-moulding elements 43 which can be used to form the casings 3, 4 with pins and sleeves according to the technical teaching of DE 10 2010 045 944 A1, to be able to lock the plastic housing 2 without screws as far as possible.

For the sake of clarity, not all these pin-moulding elements 42 and sleeve-moulding elements 43 are given their own reference signs in FIG. 5.

Furthermore, FIG. 5 also shows additional reset elements 44, to push the two halves 39, 40 apart after the hardening of the casting materials for the casings 3, 4 to be produced in the mould cavities 16. To guide the two halves 39, 40 relative to each other in this movement, guide rods 45 are attached on the half 39 on the pressure side which can be inserted into corresponding guide holes 46 on the half 40 on the locking side.

The above-mentioned sprues 34 are shown in FIGS. 4 and 5, wherein the view 33 in FIG. 5 is indicated by an arrow in FIG. 4. The sprue 34 of the permanent mould for an upper casing 15 leads into a dead-end recess 54 on the half 40 on the locking side. The casting material to be processed is collected in the dead-end recess 54 and diverted, so that the casting material exits the sprue 34 for the upper casing 3 to be produced at an angle to its ejection direction. In this way, the sprue 34 is formed as tunnel gate, and the permanent mould for an upper casing 15 as a break-away mould.

To ensure the previously mentioned precise position of the mould inserts 21 and thus the precise design of the mould cavities 16, the halves 39, 40 are provided with a double centring. A first centring roughly centres the two halves 30, 40 relative to each other. For this purpose, tool centring pins 47 are screwed onto the half 39 on the pressure side which engage in corresponding tool centring receptacles 48 on the half 40 on the locking side when the mould cavity 16 is closed. For fine centring, the mould inserts 21 are also provided with mould insert centring pins 49 on the half 39 on the pressure side, which pins can be inserted into mould insert centring receptacles 50 in the mould inserts 21 of the half 40 on the locking side.

The mould insert centring pins 49 are formed smaller than the tool centring pins 47, so that firstly the rough centring is carried out when the mould cavity 16 closes, and only when said cavity is largely closed, the fine centring is carried out.

For further reducing potential surface defects on the casings 3, 4 of the plastic housing 2, the sprues 34 and thus the injection points are arranged on central axes 51 of the mould cavities 16, so that the casting material can spread and disperse evenly after penetrating each mould cavity 16. It is also ensured that the casting material penetrates the edge regions having the above-mentioned differences in the wall thickness 37, forming the mitred surfaces 36, last and fills these regions of the mould cavity 16 evenly. It is also ensured that the casting material will not harden prematurely in the proximity of the sprue 34 due to a too-thin mould cavity region.

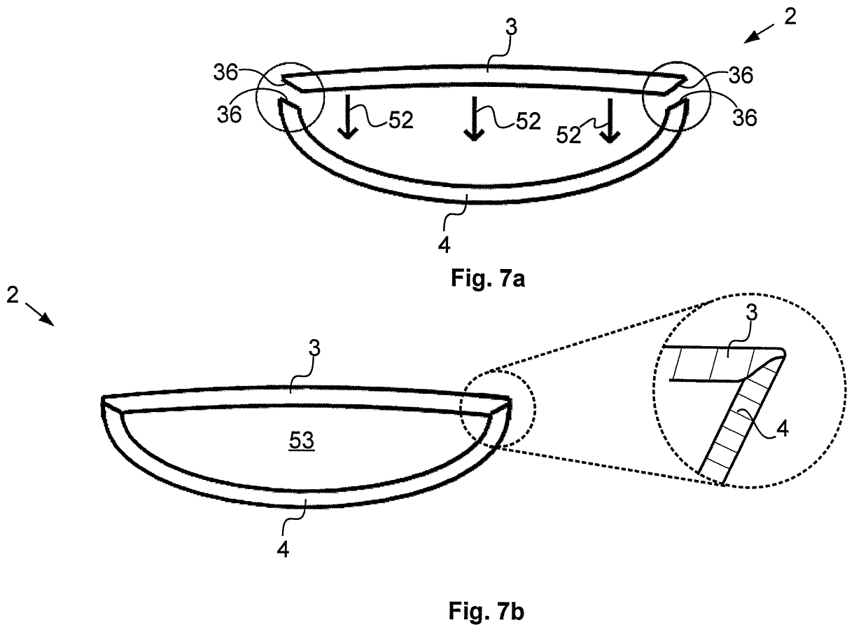

The casings 3, 4 produced by the tool and method described above can be assembled in a joining direction 52 to form the plastic housing 2 after being ejected from the tool in a way described in FIG. 7a, and thus enclose an interior space 53 indicated in FIG. 7b, in which, for example, a circuit board (not shown in further detail) can be incorporated as an electronics assembly of the remote control 1.

When assembling the upper casing 3 and lower casing 4 in the joining direction 52, the two casings 3, 4 are centred automatically at the mitred surfaces 36. This ensures a flush closure between the upper casing 3 and the lower casing 4, as shown in FIG. 7b, and thus the previously mentioned monolithic appearance of the plastic housing 2.

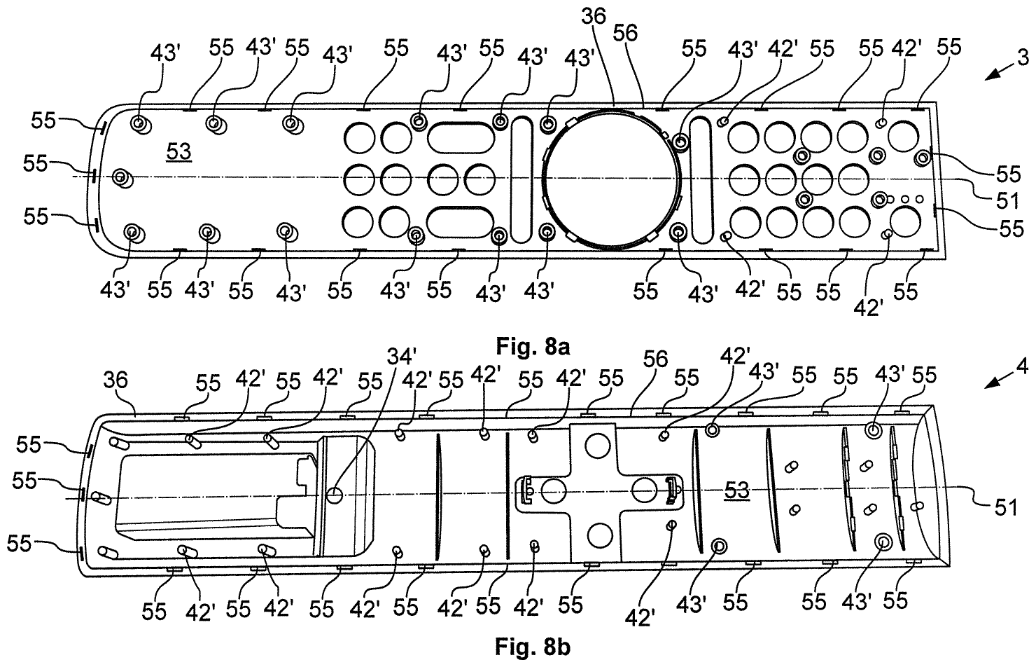

FIGS. 8a and 8b correspondingly show an example of an interior view of the produced upper casings 3 and lower casings 4. The view in FIGS. 8a and 8b thus corresponds to what is created by the half 40 on the locking side of the moulds.

The drawings clearly show the contact surfaces 55 where the ejector pins 27 touch to correspondingly eject the upper casing 3 or lower casing 4 from the half 40 on the locking side. The ejector pins 27 and thus the contact surfaces 55 are formed to be rectangular, wherein the broadside of the rectangular shape extends in the circumferential direction around the upper casing 3 or the lower casing 4.

The ejector pins 27 and thus the contact surfaces 55 are arranged along an edge 56 facing the interior space 53 of the upper casing 3 or lower casing 4. This is to ensure that the outer edges of the two casings 3, 4 close in a flush manner, and thus the monolithic appearance of the remote control is not disrupted.

The casings 3, 4 can be deepened at the contact surfaces 55 by means of the ejector pins 27.

FIGS. 8a and 8b also correspondingly show pins 42′ and sleeves 43′ formed by the pin-moulding elements 42 and sleeve-moulding elements 43, not all of which are marked with their own reference signs for the sake of clarity. FIG. 8b also shows the point 34′, at which the sprue 34 for the lower casing 4 ends. The corresponding point 34′ on the upper casing is not shown in the perspective view in FIG. 8a.

1. Plastic housing for electronic devices, in particular remote controls, comprising a first housing part and a second housing part, wherein the first housing part has a joining surface facing the second housing part, and the second housing part has a joining surface facing the first housing part, wherein the two housing parts are assembled such that the joining surfaces rest against each other, wherein the joining surfaces are in the form of mitred surfaces, and wherein contact surfaces to support ejector pins are formed at or on the mitred surfaces.

2. The plastic housing as claimed in claim 1, wherein the mitred surfaces-of the housing parts are formed at least in part so as to revolve around an interior space which is designed to enclose an electronic component of the electronic device.

3. The plastic housing as claimed in claim 2, wherein the mitred surfaces are formed so as to lead into the interior space.

4. The plastic housing as claimed in claim 1, wherein the contact surfaces are formed so as to be rectangular with a longitudinal side extending in the circumferential direction of the housing parts.

5. The plastic housing as claimed in claim 1, wherein the housing parts have a depression on the contact surfaces.

6. The plastic housing as claimed in claim 1, wherein the contact surfaces are formed on the mitred surfaces on an edge of the mitred surfaces facing the interior space.

7. The plastic housing as claimed in claim 1, which is produced by a method in which a casting material is introduced into mould cavities forming the housing parts, and air is removed from the mould cavities at the deaeration points which are positioned at or next to points in the mould cavities, at which the mitred surfaces of the housing parts are formed.

8. The plastic housing as claimed in claim 7, wherein channels leading into the mould cavities, into which channels the ejector pins are inserted, are used to remove the air from the mould cavities.

9. The plastic housing as claimed in claim 8, wherein the casting material is introduced into the mould cavities at injection points which are arranged on a side of the mould cavity opposite the side having the deaeration point.

10. The plastic housing as claimed in claim 9, wherein the injection points are arranged on a central axis in the mould cavities.

11. The plastic housing as claimed in claim 10, wherein the mould cavities are formed with mould inserts which are closed in an airtight manner at a parting plane before the casting material is injected into the mould cavities.

12. The plastic housing as claimed in claim 11, wherein the mitred surfaces of the housing parts to be formed lead into the parting plane.

13. The plastic housing as claimed in claim 12, wherein the deaeration points on the mitred surfaces are opposite the parting plane.

14. The plastic housing as claimed in claim 1, wherein:
the contact surfaces are formed so as to be rectangular with a longitudinal side extending in the circumferential direction of the housing parts; and
the housing parts have a depression on the contact surfaces.

15. The plastic housing as claimed in claim 1, wherein:
the contact surfaces are formed so as to be rectangular with a longitudinal side extending in the circumferential direction of the housing parts;
the housing parts have a depression on the contact surfaces; and the contact surfaces are formed on the mitred surfaces on an edge of the mitred surfaces facing the interior space.
